(19) United States
(12) Patent Application Publication
(10) Pub. No.: US 2026/0023331 A1
(43) Pub. Date: Jan. 22, 2026

(54) AI-Driven Control Module for Real-Time Process Optimization in Semiconductor Process Systems

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/775,892

(22) Filed: Jul. 17, 2024

(51) Int. Cl. G03F 7/00

(52) U.S. Cl. CPC G03F 7/706831; G03F 7/706841

(57) ABSTRACT

Disclosed herein is a control module for a semiconductor process system, utilizing reinforcement learning (RL) algorithms to autonomously generate and adjust process recipes. It features a comprehensive system digital twin, including subsystem, chamber plasma, and process digital twins, and employs neural network models for efficiency. Using a policy neural network and Monte Carlo Tree Search (MCTS), real-time adjustments are based on calibrated state data from various sensors, enhancing precision and adaptability in manufacturing processes.

### FIELD OF THE INVENTION

The present invention relates to semiconductor process systems, specifically to a control module and an AI machine for autonomously generating and adjusting process recipes using reinforcement learning (RL) algorithms. This invention is applicable to various semiconductor manufacturing processes, including etching and deposition, and leverages advanced AI techniques, digital twins, and real-time monitoring to enhance the precision, efficiency, and adaptability of these processes.

### BACKGROUND OF THE INVENTION

In semiconductor manufacturing, precise control over process parameters is critical to achieving the desired quality and performance of the semiconductor devices. Traditional methods of process control often rely on pre-defined recipes and manual adjustments, which can be time-consuming and may not adapt well to variations in the manufacturing environment or substrate conditions. As semiconductor devices become more complex, the need for more sophisticated and adaptive process control methods has increased.

Digital twins have emerged as a powerful tool for simulating and optimizing various aspects of semiconductor manufacturing processes. By creating virtual replicas of physical systems, digital twins enable detailed modeling and analysis of process dynamics, allowing for more accurate predictions and control adjustments. However, the computational complexity of traditional digital twins can be a limitation, particularly for real-time applications.

Reinforcement learning (RL) and AI technologies offer promising solutions for automating and enhancing process control in semiconductor manufacturing. RL algorithms, through continuous learning and adaptation, can optimize process parameters more effectively than static recipes. By integrating AI with digital twins, it is possible to develop an intelligent control system that autonomously generates and adjusts process recipes in real-time, based on the current state of the system and real-time data from various sensors.

Despite these advancements, there remains a need for an efficient and robust control system that can handle the complexities of semiconductor processes and adapt to changing conditions in real-time. The present invention addresses these challenges by leveraging a full system digital twin, including subsystem digital twins and chamber plasma and process digital twins, and employing computationally efficient neural network versions of these digital twins. Furthermore, the invention incorporates a policy neural network and Monte Carlo Tree Search (MCTS) as part of the RL algorithm to autonomously generate and adjust process recipes during substrate processing, utilizing calibrated state data from various sensors for precise real-time control.

### SUMMARY

The present inventive concept pertains to a control module and an AI machine designed for the autonomous generation and adjustment of process recipes in semiconductor process systems using reinforcement learning (RL) algorithms. The invention leverages advanced AI techniques and real-time monitoring to enhance precision and efficiency in semiconductor processing.

The control module comprises subsystem controllers, an AI engine, and a system controller. The subsystem controllers manage the operations of various subsystems within the semiconductor process system. The AI engine autonomously generates a process recipe by training a policy neural network using an RL algorithm, including Monte Carlo Tree Search (MCTS). The system controller adjusts the process recipe in real-time during substrate processing by utilizing the trained policy neural network and data provided by a real-time monitor.

Key innovations include the use of a comprehensive system digital twin, which encompasses subsystem digital twins (RF, gas, temperature, etc.) and chamber plasma and process digital twins. This digital twin approach is computationally efficient, leveraging neural network versions of the digital twins for faster processing and accuracy. Additionally, the chamber surface aging digital twin and the edge ring digital twin are crucial for real-time control, as they model the effects of plasma exposure over time, providing essential inputs to the policy neural network to maintain optimal processing conditions.

In some implementations, the AI engine is part of a cloud-based AI machine and is coupled to the system controller via a communication link. The AI engine controller within the AI engine leverages the RL engine to generate process recipes based on the system digital twin. The policy neural network, which includes input, hidden, and output layers, describes probability distributions of selected process recipe parameters across discretized levels using softmax and/or logistic functions.

The real-time monitor uses various sensors to measure parameters of RF, gas, and temperature subsystems, as well as optical sensors for light emissions from the plasma and optical reflectometry to determine structure parameters during the etching process. The system controller adjusts the process recipe based on the difference between calculated and calibrated states, using real-time data from these sensors to achieve precise control.

The method for real-time control includes training the policy neural network using the AI engine, transmitting the trained network to the system controller, updating digital twins, receiving substrate specifications, generating initial states, and process recipes, executing actions, calculating post-action states, calibrating states with real-time data, and repeating these steps until the terminal state is reached. This continuous adjustment ensures optimal process conditions and high precision in semiconductor manufacturing.

This invention represents a significant advancement in semiconductor processing by integrating AI-driven autonomous recipe generation and real-time adjustment, ensuring high precision, efficiency, and adaptability in manufacturing processes. The incorporation of chamber surface aging and edge ring digital twins is particularly important, as they allow for real-time adjustments based on the wear and tear of these components, thereby enhancing the accuracy of the process control.

### BRIEF DESCRIPTION OF THE DRAWINGS AND TABLES

FIG. 1: Illustrates a diagram of an exemplary process system.

FIG. 2A: Depicts a functional diagram of an AI machine coupled to a fleet of system controllers for the process systems.

FIG. 2B: Depicts detailed functional blocks of the AI engine.

FIG. 3: Presents a schematic representation of a system digital twin.

FIG. 4: Portrays a neural network representation for the system digital twin.

FIG. 5: Displays a process flow example using atomic layer etching (ALE), mapped for the RL processes to autonomously generate a process recipe.

FIG. 6: Shows a schematic representation of a policy neural network, integral to the RL process.

FIG. 7: Reveals a schematic diagram of an exemplary algorithm for RL, utilizing an MCTS program to autonomously train a policy neural network.

FIG. 8: Illustrates a flowchart describing a process of autonomously training of the policy neural network and generating a process recipe through RL.

FIG. 9A: Showcases a flowchart describing a process for real-time controlling of a process system through dynamic adjustment of a process recipe.

FIG. 9B: Illustrates a schematic diagram of a state calibration neural network.

Table 1: Outlines design parameters describing subsystem structures and topologies.

Table 2: Summarizes parameters that describe structures pre- and post-processing, using the ALE process as an example.

Table 3: Showcases selected ALE process recipe parameters, discretized into levels suitable for implementing RL.

### DETAILED DESCRIPTIONS

This section delves into the specific embodiments of the present invention, aiming to provide a comprehensive understanding. It is important to note that while certain implementations are described to illustrate the inventive aspects clearly, any alterations and modifications that fall within the scope of the appended claims are intended to be encompassed by this disclosure. These detailed descriptions underscore the innovative features of the invention, setting it apart from existing technologies.

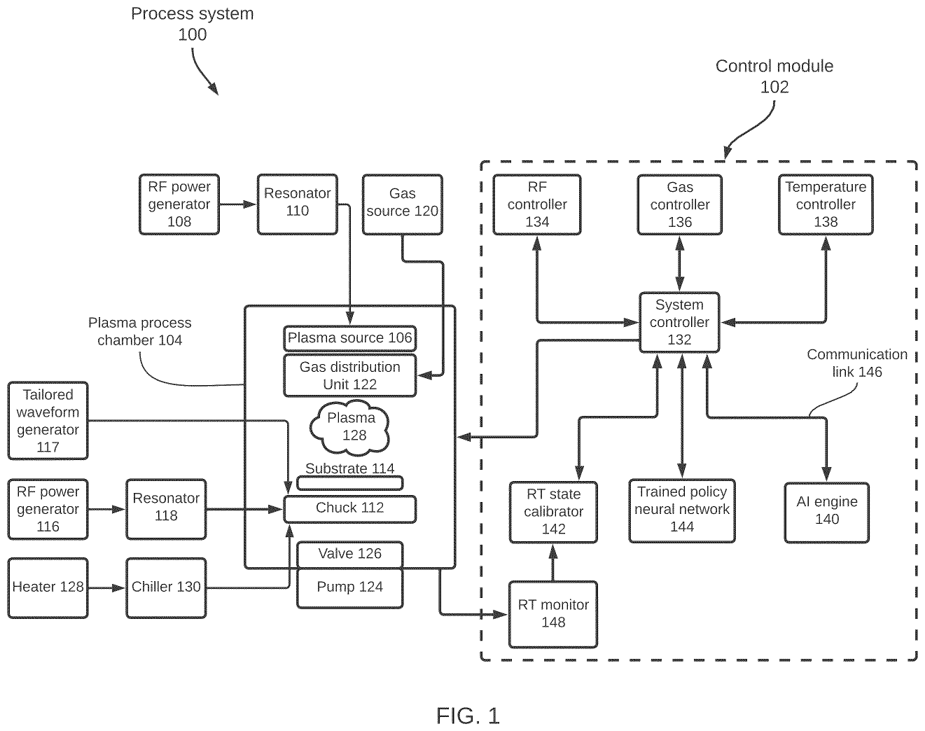

FIG. 1 illustrates an embodiment of a process system, designated as 100. The process system is generic for plasma-enhanced etching or deposition processes. For example, the process system 100 can be employed for reactive ion etching (RIE) or atomic layer etching (ALE). It can also be utilized for plasma-enhanced chemical vapor deposition (PECVD) or atomic layer deposition (ALD). In some cases, subsystems related to plasma generation may be absent, the process system becomes a thermal process system. The inventive concept presented herein is generic and can be applied to any type of semiconductor process system. The plasma-based process system with a vacuum chamber is used for illustration only and should not limit the scope of the inventive concept.

The process system 100 further includes a control module, denoted as 102. The components of the control module 102 are depicted within a dashed box as shown in FIG. 1. It should be noted that some components of the control module 102 may not be local to the process system and may be in the cloud.

The process system 100 includes a plasma process chamber 104, constructed to maintain a vacuum suitable for plasma processing. Within this system, a plasma source 106 is situated to receive radio frequency (RF) power from an RF power generator 108 via a resonator 110. The plasma source 106 may be realized in various configurations, such as an inductively coupled plasma (ICP) source or a transformer coupled plasma (TCP) source, among others.

The RF power generator 108 can operate at single or multiple frequencies—for instance, 13.56 MHz, 2.0 MHz, and 40 MHz may be used. The role of the resonator 110 is to match the output impedance of the RF power generator 108 with the impedance of the plasma process chamber 104, considering the impedance characteristics of the transmission lines. This resonator 110 typically comprises inductors and capacitors and may include mechanically adjustable capacitors. Alternatively, in other embodiments, the resonator 110 might exclude mechanically adjustable capacitors.

Impedance adjustments may be realized by varying the operating frequencies of both the RF power generator 108 and the resonator 110. During a process, the plasma is likely to exhibit variable states, which present different impedance levels. To maintain efficient energy transfer and minimize power reflection from the plasma process chamber 104 back to the resonator 110, it may be necessary to fine-tune the frequency for each distinct state of the plasma to ensure the resonator 110 remains in a resonating condition.

The plasma process chamber 104 is further outfitted with a chuck 112 that supports a substrate 114. The chuck 112 can be designed as an electrostatic chuck (ESC) or a vacuum chuck, depending on the process requirements. When an ESC is utilized, the chuck 112 is electrically connected to an RF power generator 116 via a resonator 118. Like resonator 110, resonator 118 requires tuning to a resonating state by adjusting its operating frequency. The operating frequencies of RF power generator 116 may differ from those of RF power generator 108. For instance, generator 116 may operate at a substantially lower frequency than generator 108.

The RF power generator 116 provides a bias to the chuck 112. This bias is delivered through a blocking capacitor, which, while not depicted, is standard in the field. Alternatively, a tailored waveform generator 117 may be employed to supply a bias to the chuck 112. The tailored waveform can significantly narrow the distribution of ion energies produced by the ignition of plasma 128 within the process chamber 104. Depending on the implementation, the tailored waveform generator 117 may be connected to the chuck 112 alone or in conjunction with the RF power generator 116 and resonator 118 to provide the required bias.

The operation of the RF subsystem, including the RF power generators, resonators, and plasma source, is managed by an RF controller 134. This controller communicates with and is subordinate to a system controller 132. The RF controller 134 and the system controller 132 are components of the control module 102.

The plasma process chamber 104 incorporates a gas distribution unit 122, tasked with delivering process gases from a gas source 120 into the chamber. The gas distribution unit 122 can take various forms, such as a gas injector or a showerhead, and may include a side injection feature near the inner surfaces of the chamber body. The gas source 120 typically draws from a facility's gas supply through a gasbox and uses a combination of valves, pressure regulators, and mass flow controllers (MFCs) to regulate the gas flow into the chamber. In some other implementations, precursor delivery systems for delivering a precursor in gas, liquid, or even solid state may also be employed (not shown in the figure).

Additionally, the plasma process chamber 104 houses a pump 124, which may be a turbomolecular pump or another suitable type, designed to evacuate gases and by-products from the chamber. A valve 126, generally positioned atop the pump 124, modulates the evacuation rate from the chamber. The chamber pressure is monitored by a manometer (not illustrated), which triggers adjustments to the set point of an actuator of the valve 126 to maintain a pressure suitable for a vacuum-based process.

The gas distribution subsystem, also referred to as the gas subsystem, which includes the gas distribution unit 122, gas source 120, pump 124, and valve 126, is overseen by a gas controller 136. This controller is connected to the overarching system controller 132, ensuring integrated management of the process system 100. The gas controller 136 and the system controller 132 are components of the control module 102.

The plasma process chamber 104 is also equipped with a temperature control subsystem, also referred to as the temperature subsystem, to maintain the desired thermal conditions for the substrate and the chamber. In the embodiment exemplified in FIG. 1, the temperature of the chuck 112 is regulated by a temperature controller 138, which operates a heater 128 and a chiller 130, as well as a temperature sensor (not depicted). The chuck 112 may be designed with multiple zones, each maintained at a distinct temperature. Additionally, temperature control for other components within the process chamber, such as the gas distribution unit 122 and various chamber surfaces, may be required and is implemented as is common in the industry. The temperature subsystem is controlled by a temperature controller 138 coupled to the system controller 132; both controllers are components of the control module 102.

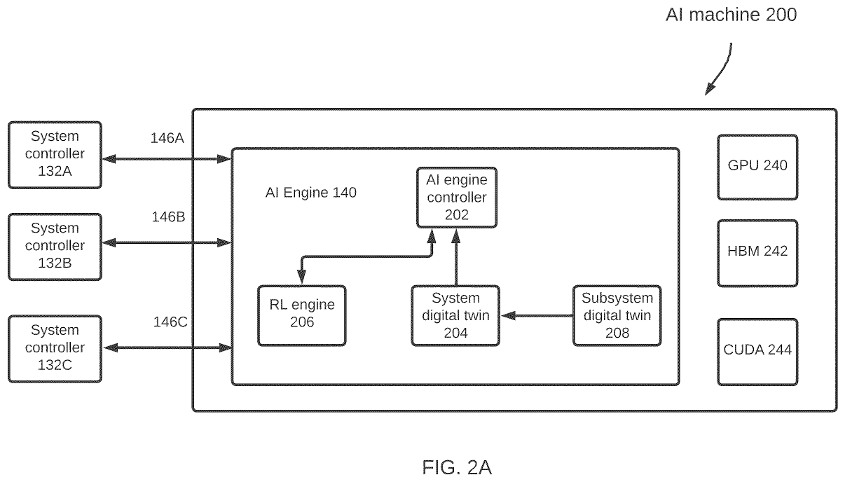

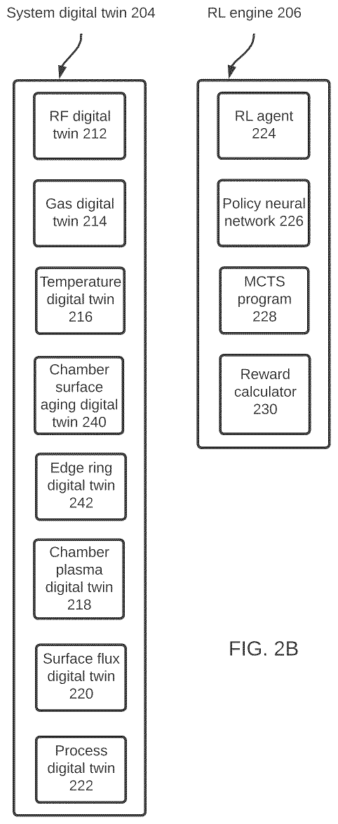

The system controller 132 is coupled to an AI engine, denoted as 140. The AI engine is designed to autonomously train a policy neural network and generate a process recipe based on a system digital twin and a learning algorithm like RL. Generating a process recipe demands significant computational resources; hence, the AI engine 140 may be in the cloud as part of an AI machine 200 (FIG. 2). The system controller 132 is local to the plasma process chamber 104. The system controller 132 is coupled to a real-time (RT) state calibrator 142 and a trained policy neural network 144. The system controller 132 receives the trained policy neural network from the AI engine 140. The system controller 132 leverages the trained neural network 144 to generate a process recipe based on inputs and output specifications of a substrate to be processed. The policy neural network 144 takes additional inputs for the chamber interior surfaces and the edge ring. Both could be a function of the history of plasma-based processing and preventive maintenance (PM) procedures. The process recipe consists of a chain actions, each of the action leads to a new state. A state is a description of structures in the substrate and an action is a process step of the recipe. Subsequently, the system controller 132 initiates a processing event of the substrate using the plasma process chamber 104. The RT state calibrator 142 receives real-time measurement results from the RT monitor 148 and calibrates a calculated state at a moment to the measurement results. The system controller 132 evaluates the difference between calculated and calibrated state and decides if the process recipe is required to be adjusted by employing the trained policy neural network 144. In some implementations, the RT state calibrator 142 and the trained policy neural network 144 can be implemented as software programs executable by the system controller 132. In some other implementations, they may be implemented as firmware or hardware. In still other implementations, they may be implemented as a combination of software, firmware, and hardware. For example, the trained policy neural network 144 can be implemented as a hardware form of the neural network. The weights of the network 144 can be transmitted from the AI engine 140. In one implementation, the trained policy neural network 144 can be implemented as an analog computing unit.

The RT monitor 148 includes sensors for measuring the status and performance of the RF, gas, and temperature subsystems. The RT monitor 148 may also include sensors for optical emission spectroscopy for characterizing neutrals in the plasma. The RT monitor 148 may further include sensors for optical reflectometry for directly measuring the structure progression of the substrate being processed.

FIG. 2A showcases an embodiment of the AI machine 200. In one implementation, the AI machine is a computer optimized for AI applications through advanced hardware and software modules. The hardware module includes advanced chips like a graphics processing unit (GPU) 240 and high-bandwidth memory (HBM) 242. These components are integrated using advanced packaging technologies to achieve the very high bandwidth required for AI applications. The software module further includes compute unified device architecture (CUDA) 244. These hardware and software modules enable the AI machine 200 to conduct highly efficient parallel computing, such as the algorithms used for RL.

The AI machine 200 also includes an AI engine 140, which enables autonomous operations for training a policy neural network which is used to generate a process recipe. The AI engine 140 further comprises an AI engine controller 202, which controls operations of the AI engine. The AI engine controller 202 can be implemented leveraging the GPU 240, HBM 242, and CUDA 244. The AI engine 140 further includes an RL engine 206 responsible for autonomously generating a process recipe through RL by leveraging a system digital twin 204, which replicates the operations of the process system in a virtual environment. The system digital twin 204 includes various subsystem digital twins 208.

The AI engine 140 in the AI machine 200 can serve multiple process systems. As shown in FIG. 2A, the AI engine 140 can be coupled exemplarily to system controllers 132A, 132B, and 132C through communication links 146A, 146B, and 146C. The communication links can take various forms including, but not limited to, optical, wireless, and wired communication channels as known in the art.

FIG. 2B depicts more detailed functional blocks of the AI engine 140. The system digital twin 204 comprises an RF digital twin 212 for simulating the operations of the RF subsystem, a gas digital twin 214 for the gas subsystem, and a temperature digital twin 216 for the temperature subsystem. The system digital twin 204 further comprises a chamber plasma digital twin 218, a surface flux digital twin 220, and a process digital twin 222.

Some chamber parts may have their surface conditions or dimensions affected by exposure to harsh plasma over time. Additionally, surface conditions can be altered by applying a preventive maintenance (PM) procedure, such as surface cleaning. Therefore, it is important to capture these effects by incorporating a chamber surface aging digital twin 240 and an edge ring digital twin 242. The details of these subsystem digital twins will be discussed in the following sections.

The RL engine 206 further includes an RL agent 224, which is typically a software program stored in a storage medium of the AI engine controller 202 responsible for executing the RL process. A policy neural network 226 and an MCTS program 228 are employed by the RL agent 224 to build a search tree and to learn by evaluating actions against rewards. The rewards are calculated by a reward calculator 230 for each completed simulated case using the system digital twin 204.

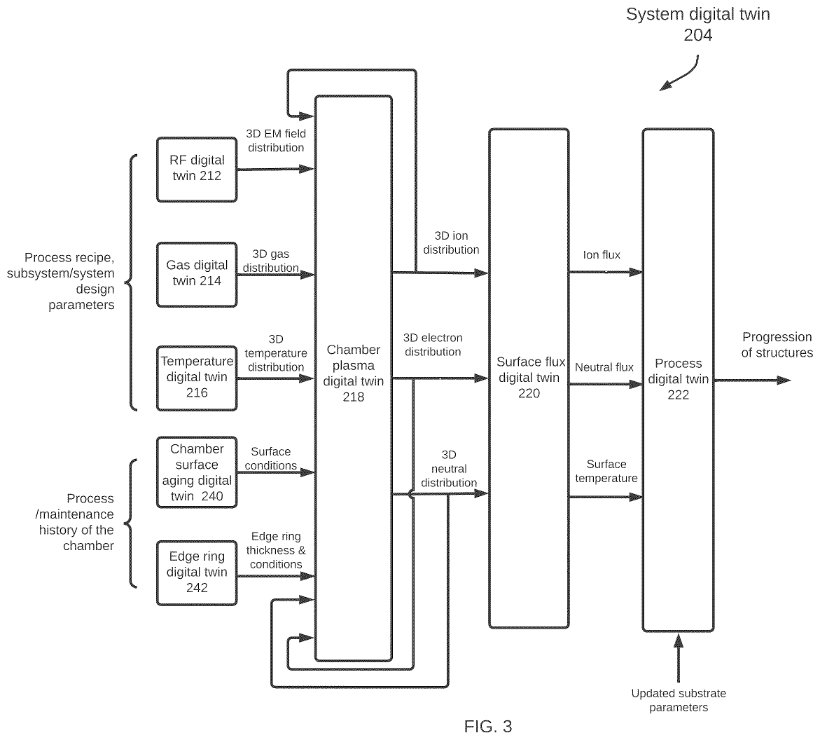

FIG. 3 illustrates schematically a flow diagram of the system digital twin 204. The RF digital twin 212, the gas digital twin 214, and the temperature digital twin 216 take related process recipe parameters and subsystem and system design parameters as their inputs. The RF digital twin 212 is designed to simulate the RF subsystem, which includes at least RF power generators and resonators. In some cases, it may also include a tailored waveform generator for the bias, although the tailored waveform generator is typically not operated in the RF range. In one implementation, the RF digital twin 212 includes a SPICE model for the RF circuits, which determines the RF power deposited into the plasma source during a time step. A Maxwell's equation solver is subsequently employed to compute the electromagnetic (EM) field distribution inside the chamber, considering the chamber structure parameters.

The RF digital twin 212 receives recipe parameters like RF power and initial operating frequency for the step. A set of system and subsystem design parameters, such as RF circuit topology, values of each component, structures, and parameters of the plasma source, and chamber structure parameters, are typically stored in a storage medium of the AI engine controller 202. A set of exemplary design parameters for the RF subsystem is listed in Table 1. The RF digital twin 212 can be used to determine the resonating frequencies of the RF subsystems. In another embodiment, more than one RF digital twin may be used. For example, the plasma source and the chuck bias may be modeled by different RF digital twins.

Similarly, the gas digital twin 214 replicates functions of the gas subsystem, encompassing elements like the gas source 120, the gas distribution unit 122, the pump 124, the valve 126, and the manometer (not pictured).

The gas digital twin 214 receives process recipe parameters like the flow rates of process gases. For example, for an ALE process, the gas digital twin 214 receives the flow rate for the first and second process gases and the chamber pressures for the surface modification step and the sputtering step, respectively. The design parameters for the gas delivery systems include the design parameters for the gas distribution unit as listed exemplarily in Table 1. If it is a showerhead, the design parameters will include its size, volume, distribution of injection channels/holes, and their sizes. The shape and size of the plasma process chamber are also important input parameters for the gas digital twin 214. The output of the gas digital twin 214 includes three-dimensional (3D) gas distribution (e.g., density, partial pressure, velocity, and residence time) inside the gas distribution unit 122 and in the plasma process chamber 104. In some implementations, the gas distribution along gas lines from the gas source 120 to the entry of the gas distribution unit 122 will also be modeled. The gas distribution can be simulated using methods based on fluid dynamics by leveraging finite element techniques or other advanced computational techniques.

The temperature digital twin 216 mirrors the temperature subsystem, which includes the heater 128, the chiller 130, and temperature sensors (not pictured). Besides the chuck temperature controls, it may additionally incorporate temperature regulation for other chamber parts such as the gas distribution unit 122.

The temperature digital twin 216 receives process recipe parameters like chuck temperatures. In some cases, the chuck 112 may be divided into zones, each with a different temperature specified by a process recipe. The input parameters to the temperature digital twin 216 further include design parameters for the heater and chiller as shown exemplarily in Table 1. For the heater 128, the design parameters include its locations inside the chuck or other chamber parts, as well as a range of its operating power. The design parameters further include thermal conductivity for various materials and their interfaces. For the chiller, the design parameters may include the type of coolants, flow rates of the coolants, and the number and locations of conduction channels. The temperature digital twin may apply numerical simulation methods like the finite element method to simulate the temperature distribution of the chuck, substrate surface, and inner surface of the plasma process chambers.

It should be noted that treating the digital twins 212, 214, and 216 independently may oversimplify the real world. For example, the RF power deposited into the chamber may affect the temperature of the substrate surface. Some of these interactions among different subsystem digital twins should be considered carefully.

The chamber interior surfaces and dimensions of certain parts are a function of time exposed to the plasma. The chamber surface aging digital twin 240 is used to model such “memory” effects for selected chamber surfaces like the surfaces of the window, the gas injector, or the showerhead. The input parameters include surface material, accumulated ion and neutral exposure, and treatment histories resulting from a PM procedure. The history of PM plays an important role in the conditions of the surfaces due to the clean procedures. The outputs include a set of surface parameters like surface structures, composition, roughness, and sticking coefficient. These parameters combined have effects on the chamber neutral and ion distributions.

The plasma process chamber 104 includes some consumable parts, whose dimensions may be reduced as a function of plasma exposure. Some of the changes may have significant impacts on the process performance. For example, an edge ring is typically employed along the edge of the substrate being processed to improve plasma and temperature uniformity in modern etching chambers. When exposed to the plasma for a period, a reduction in the edge ring thickness can alter the process performance at the edge of the substrate substantially. The edge digital twin 242 is used to model such effects. The inputs of the edge ring digital twin include the edge ring material, its structure parameters like the initial height of the edge ring. The input parameters further include the history of the edge ring being exposed to the ions and neutrals in the plasma. The history of PM can also be a factor. The outputs of the edge ring digital twin include the height of the edge ring. In some implementations (not shown in the figure), the temperature and electrical potential of the edge ring can be included as the input parameters to determine the edge ring erosion rate.

The outputs of the subsystem digital twins feed into the chamber plasma digital twin 218. During a specific time step of a process, the chamber plasma digital twin 218 models the plasma inside the chamber 104 and outputs 3D distributions of electrons, ions, and neutrals. The distributions at a specific time are a function of the EM field, gas, and temperature at that moment, as well as the distributions of electrons, ions, and neutrals prior to that moment. Therefore, the distributions of the electrons, ions, and neutrals need to be determined in a recurring manner. As shown in FIG. 3, the outputs of the chamber plasma digital twin from the current time step can serve as inputs for the same digital twin for the next time step. Each simulation event is for a predetermined time step defined by the AL engine controller 202.

After the 3D distributions of ions and neutrals are known, the surface flux digital twin 220 calculates and outputs the ion flux and neutral flux toward the surface of the substrate. Additionally, the digital twin 220 may output the surface temperature of the substrate by working together with the temperature digital twin 216. The plasma sheath above the substrate is critically important for determining the ion flux, which greatly impacts the etching behavior. The formation of the plasma sheath is well understood in the art and can be modeled accurately using the chamber plasma digital twin 218.

The outputs of the surface flux digital twin 220 feed into the process digital twin 222 to simulate the process in the plasma process chamber 104. The updated substrate parameters or its state serves as the inputs to the process digital twin 222. The current state of the substrate parameters is used by the process digital twin 222 to determine its outputs.

The flow depicted in FIG. 3 represents a snapshot of the process during the time step in the plasma process chamber 104. Therefore, the output of the process digital twin is a progression of the structures during the time step.

During each time step, the accumulated ion and neutral fluxes should be counted. Details of ion and neutral distribution are important for the process in the plasma process chamber 104. For ions, their energy and angular distributions during the step are critically important and can vary based on location on the surface of the substrate. The outputs of the surface flux digital twin 220 should include such critical details. Similarly, for neutrals, the density, thermal energy, and activation energy are important parameters for the substrate surface undergoing the process.

It should be noted that the designs of the subsystem, chamber plasma, and the process digital twins are exemplary herein. There could be many variations in implementation strategies. In some implementations, the chamber plasma digital twin and the surface flux digital twin could be combined into a single digital twin. In other implementations, the surface flux digital twin may be combined with the process digital twin. Additionally, the RF subsystem digital twin may be broken down into several digital twins to represent the plasma source and the bias units separately. Similarly, the temperature digital twin can be divided into two or more digital twins, with at least dedicated digital twins for the chuck and the gas distribution unit, respectively. All such variations are obvious and should fall within the inventive concept of the present inventions.

Implementations of the digital twins by neural networks can follow the same strategy of dividing the process system into subsystems.

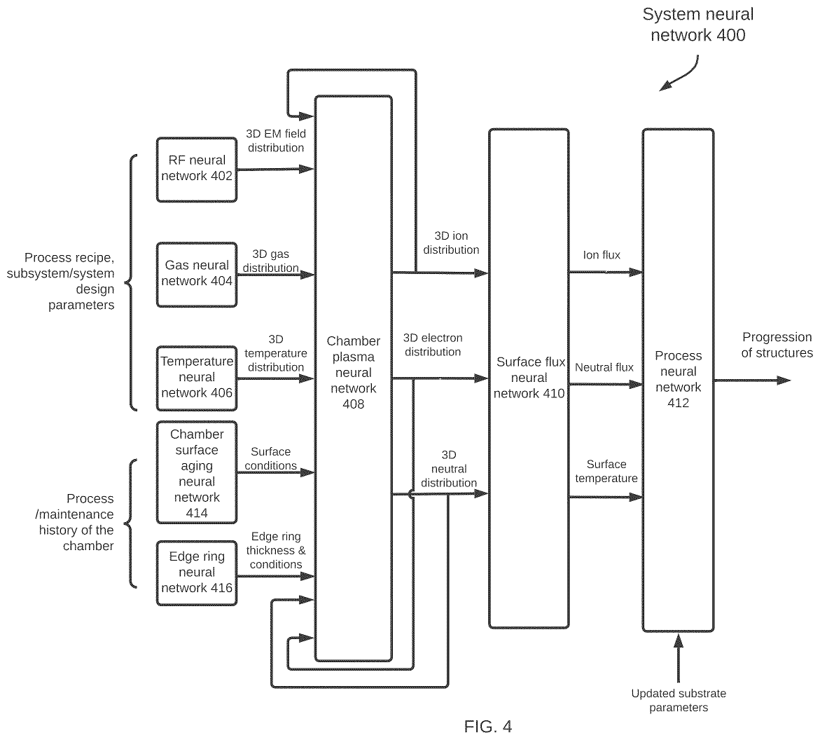

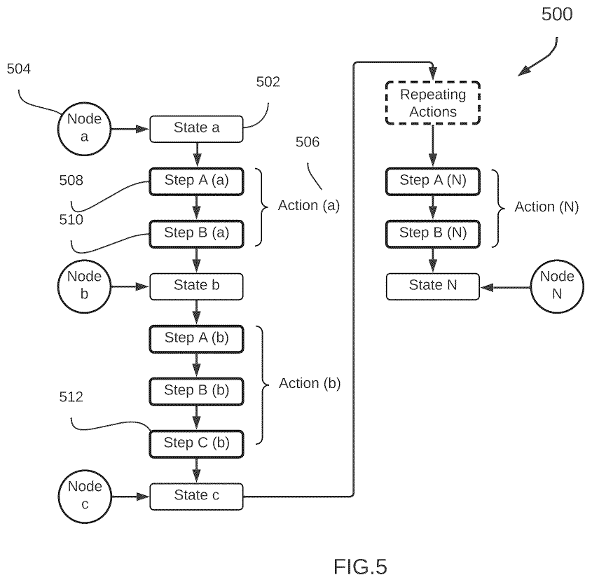

FIG. 4 illustrates an exemplary process system represented as a system neural network 400. In this embodiment, the subsystem digital twins are reconstructed using various neural networks. The RF digital twin 212 serves as the basis for training the RF neural network 402. Using the plasma source 106 attached to the RF power generator 108 and the resonator 110 as an example, one can begin by constructing a SPICE model to simulate the RF power generator 108 and resonator 110, including transmission line effects. The SPICE model outputs an initial AC current and voltage for coils of the plasma source 106, necessitating an assumed initial impedance for the plasma 128. Following this, a numerical simulator applies Maxwell's equations to predict the EM field distribution within the plasma process chamber 104.

The wealth of simulation data generated by the RF digital twin 212 becomes the training set for the RF neural network 402. The inputs for the neural network 402 include RF circuit topology and parameters such as the values of the inductors, capacitors, resistors, and transistors within the generator and resonator, along with detailed modeling of effects and transmission lines.

Furthermore, the RF neural network 402 considers the chamber structure parameters—dimensional specifics, positions of the chuck and the gas distribution unit, and material properties of these components, as listed exemplarily in Table 1.

Some parameters are measurable and thus provide a more substantial weight during the training of the RF neural network 402. For instance, sensors might track the current and voltage alterations in the coils of the plasma source or the reflected power at the resonator's output node. A B-dot sensor with multiple small coils could be positioned within the chamber to map the magnetic field distribution in an experimental setup. The information gleaned from these sensors not only informs the training process but ensures that the RF neural network 402 is closely aligned with the real-world behaviors observed.

Utilizing a neural network for modeling the bias portion of the RF subsystem focuses on the electric field generated initially in response to the applied RF power. Unlike the magnetic field concerned with plasma generation, the bias deals with the electric field affecting the substrate surface.

Transitioning to the gas dynamics within the process system 100, we approach the gas distribution neural network 404, which is informed by the gas digital twin 214. Numerical algorithms based on fluid dynamics are the foundation for determining the gas distribution within the chamber 104. This complex interplay involves the gas inflow from the gas distribution unit 122, the outflow managed by the pump 124 and the valve 126, which is influenced by the chamber's conductance and volumetric parameters. While numerical simulations offer accuracy, their demand for computational resources and time constraints necessitate a more efficient approach for real-time applications, hence the establishment of the gas distribution neural network 404.

The gas distribution neural network 404 is trained with simulation data reflecting various parameters, including the types and flow rates of gases, the design of the gas distribution unit 122, the pump's capacity 124, and the set point of the actuator of the valve 126, along with chamber dimensions and conductance. Some of the design parameters are listed in Table 1. The gas distribution unit 122, implemented as an injector, a showerhead, or a combination of both, can affect the gas distribution in the process chamber 104. The size, quantity, and distribution of channels/holes inside the injector and the showerhead are important design parameters. Gas pressure within the process chamber, monitored by a manometer, provides measurement data that enhances the training of the gas distribution neural network 404, often weighted more significantly than the simulation data to ensure the model's relevance to actual conditions.

Parallel to these developments is the creation of the temperature neural network 406, drawn from the temperature digital twin 216. This neural network is dedicated to mapping the thermal landscape within the plasma process chamber, particularly at the substrate surface. Its training originates from numerical models that simulate heat interactions and distributions. Inputs for the temperature neural network 406 include chuck and chamber parameters affecting heat generation and thermal conduction. In scenarios involving an ESC, the thermal characteristics of the ESC and the heat conduction efficiency, potentially affected by helium pressure used as a medium, are critical. Additional chamber specifications, such as size and construction materials, also influence the model. Temperature readings from sensors within the chuck 112 and the chamber 104 provide valuable real-world data, which, when used to train the temperature neural network 406, may carry heavier weights over simulated data due to their direct measurement of the physical environment. This balance of simulated and measured data ensures that the various neural networks closely mimic the actual processes, thereby enabling accurate predictions within the process system.

The chamber surface aging neural network 414 can be trained by the data generated by the chamber surface digital twin 240. Furthermore, the measurement data for specific chamber materials or surfaces can be generated utilizing specially designed testing apparatus and be used for the training. The neural network 414 mimics the digital twin 240 with significantly improved computing efficiency.

The edge ring neural network 416 can be trained by synthetic data generated from the edge ring digital twin 242. The erosion rate of the edge ring can be determined by measuring its height reduction against the time exposed to the plasma. The measurement data can then be used to improve the accuracy of the training.

FIG. 4 elucidates the intricacies of the system neural network 400, where the outputs of the subsystem neural networks act as inputs to the chamber plasma neural network 408. The chamber plasma digital twin 218 serves as the foundation for the chamber plasma neural network 408, enabling a sophisticated representation of the plasma within the etching chamber.

To simulate the movement of particles within the plasma, either a Monte Carlo or a numeric plasma simulator can be used to visualize the three-dimensional distribution of electrons, ions, and neutrals. This is crucial because electrons, which are significantly lighter, move more rapidly than ions, leading to the creation of a sheath on the surfaces within the chamber. This sheath plays a pivotal role in ion acceleration toward the substrate, a process essential for sputtering but potentially counterproductive during surface modification.

The training of the chamber plasma neural network 408 integrates simulation data for faster computation and higher efficiency. However, to refine its predictive capabilities, it may also assimilate measurement data gathered from sensors within the chamber, such as optical emission spectroscopy and hairpin sensors that gauge electron density. This measurement data may be given a heavier weight over the simulated data to ensure that the outputs of the plasma neural network 408 are as realistic as possible.

The dynamic nature of the plasma environment is captured by the recurrent neural network (RNN) design of the chamber plasma neural network 408. This means it can process temporal sequences, taking snapshots of plasma conditions at a given time and incorporating them into the model for future predictions. It is an ongoing cycle where the neural network's previous outputs become part of the input data for the next time step, mimicking the continuous evolution of the plasma state.

Once the chamber plasma neural network 408 has computed the 3D distributions, the ion and neutral fluxes to the substrate surface can be determined based on a surface flux neural network 410. The ion and neutral fluxes, along with the surface temperature of the substrate, are then taken as inputs for the process neural network 412. The process neural network 412 can be trained based on the data generated by the process digital twin. The outputs of the process neural network 412 further include the progression of the structures in the substrate.

Ultimately, the chamber plasma neural network 408 and the surface flux neural network 410 yield valuable outputs beyond just fluxes; they also provide critical insights into the surface temperature by working together with the temperature neural network 406. The accumulated fluxes during the time steps should also include valuable information about ion energy and angular distribution, as well as neutral thermal energy and activation energy. These parameters are essential for fine-tuning the process in the plasma chamber to achieve the desired etching precision and substrate surface quality.

It should be noted that FIG. 4 showcases an embodiment 400 of a full neural network implementation of the system digital twin 204. In other embodiments or implementations, some functional blocks may not be implemented as neural networks. For example, the surface flux neural network 410 may be an analytical model. Hence, embodiment 400 is exemplary. There may be many variants of implementations by combining models, lookup tables, analytical models, numerical models, and Monte Carlo models for selected building blocks of the system digital twin 204. All such variants fall within the scope of the present inventive concept.

An ALE process is employed herein as an example to illustrate a system and method for autonomously generating a process recipe through the application of an RL algorithm. FIG. 5 illustrates an ALE process flow 500, which is suitable for implementing the RL algorithm. An exemplary ALE process typically involves alternating between a surface modification step A and a sputtering step B in a cyclic manner. It should be noted that steps A and B herein are commonly called half cycles of the ALE process, which are different from the time steps we discussed previously for simulating plasma behavior in the chamber. The time steps are significantly shorter than the step A and the step B of the ALE process.

During step A, the surface of the substrate 114 is chemically altered using chemically active neutrals formed in the plasma, which is generated by a plasma source powered by an RF power generator. A halogen gas, such as chlorine, is often introduced to produce neutrals for this purpose. During this surface modification step, the bias to the chuck is typically set to zero to minimize the impact of ions on the substrate, thereby preserving the integrity of the ALE process.

Conversely, during the sputtering step B, an inert gas like argon is introduced to generate energetic ions that physically remove the chemically modified layer from the substrate by sputtering. At this juncture, a bias is typically applied to the chuck through the RF power generator and resonator.

Between these steps, a purge step may be employed to transition the gases from step A (508) to step B (510) or vice versa without intermixing the two process gases. The purge steps are not shown in FIG. 5. Step A (a) shown in FIG. 5 represents step A at the node a. Similarly, step B (a) represents step B at node a.

In some applications, particularly when etching high aspect ratio structures, an additional deposition step C (512) can be optionally included along with steps A and B. This step C is strategically inserted into the ALE cycle sequence but at a less frequent rate compared to steps A and B. Its primary function is to protect the sidewalls of the etched structures, thus preventing lateral etching that may arise due to the angular distribution of the ions. Step C (b) represents step C at the node b.

An ALE process runs in cycles, with each cycle including a step A and a step B. As shown in FIG. 5, an ALE cycle starts from a state and completes in another state. A state is denoted as 502, which describes the substrate undergoing processing. State a represents the state at the node a. Specifically, in an ALE process, the state describes one or multiple structures. The description of the state includes, but is not limited to, parameters describing a structure being etched, such as depth, critical dimensions, profiles, and loadings as shown exemplarily in Table 2. The state 502 is associated with a node 504. Hence, state a is associated with the node a. The ALE cycle starts initially at a node with a state, executes an action, denoted as 506, by selecting process recipe parameters using the policy neural network 226 and MCTS program 228, and completes at another node with an updated state. In FIG. 5, Action (a) denotes the action triggered by the ALE recipe at the node a.

It should be noted that a node can lead to more than one node through different actions. If the recipe parameters are continuous, the available new nodes would be infinite. Conversely, if the recipe parameters are discretized to limited levels, the available new nodes will be limited.

A complete ALE cycle is used for an action in FIG. 5 as an example only. In some other implementations, a half cycle can be employed to separate the nodes. In such a case, the action is either a surface modification step A, a sputtering step B, or even a deposition step C. All such variations will fall within the scope of the present inventive concept.

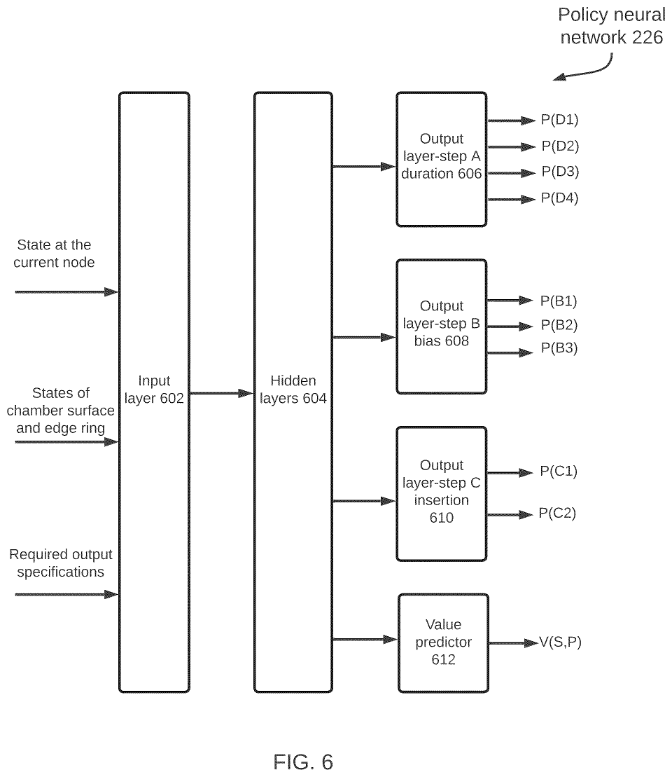

FIG. 6 showcases an exemplary policy neural network 226. The network 226 comprises an input layer 602 for receiving the state of the current node and required output specifications as its inputs. For the real-time control, it is critically important that chamber parameters which are a function of the chamber age exposed to the plasma should be included as an input of the policy neural network 226. In the context of the present invention, the outputs of the chamber surface aging digital twin 240 and the edge ring digital twin 242 which describe the real-time state of the chamber interior surface, and the edge ring height are the inputs for the policy neural network 226. Hence it can be used effectively to predict the actions from the state. It should also be noted that the output specifications herein are final requirements after completion of the entire process, not a step of the process. Inclusion of the output specifications as one of the inputs of the policy neural network 226 makes it more generic and able to deal with changes in output specifications. In some other implementations, the inputs include only the state.

The policy neural network 226 further includes one or more hidden layers, denoted as 604, for processing received data from the input layer 602. The policy neural network 226 further comprises an output layer which may include multiple parts, each part further includes several parameters describing softmax or logistic functions. The parts of the output layer are depicted in FIG. 6 as 606, 608, and 610 exemplarily, each delivering a probability distribution of a discretized process recipe parameter with more than one level. Furthermore, the output layer includes a value predictor 612 for predicting the value of the state based on the current policy represented by the policy neural network 226 with the current weights. When the policy neural network 226 is employed for designing the process system, the discretized levels for the recipe parameter should include limits of the parameter. Intrinsic capabilities of the process system will need to be evaluated against the limits, defined by the ranges of the parameters.

FIG. 6 exemplifies the policy neural network designed for the ALE process, wherein three recipe parameters are selected. The first part 606 delivers probability distributions of 4 levels of the duration of step A, denoted as D1, D2, D3, and D4, where P(D1), P(D2), P(D3), and P(D4) are the probabilities of each level, respectively. A softmax function can be utilized to describe such 4-level probability distribution with 4 output parameters. The probability can then be calculated accordingly. Similarly, the second part 608 outputs probability distributions of 3 levels of the chuck bias of step B. The third part 610 delivers probability distributions of 2 possibilities for either including or excluding a step C after step B in the ALE cycle. The two-level probability distribution can be represented by a logistic function. Exemplary ALE recipe parameters for this implementation are depicted in Table 3. The exemplary input parameters are listed in Table 2.

It should be noted that different sets of ALE recipe parameters may be selected, and different levels may be selected for each parameter. If the process system 100 is employed for a different type of process like deposition, the parameter selection may be different. The example herein is for illustration purposes and should not be considered a limit for the inventive concept. Furthermore, the selection of the recipe parameters and levels may be dynamic. It means they may be modified during the execution of an RL algorithm. In one implementation, after a predetermined number of simulated cases are executed, the RL agent 224 may decide to narrow down the parameter space and adjust ranges and levels of the parameters to accelerate the convergence of the RL algorithm. In some implementations, old parameters may be removed, and new parameters may be added. In still some other implementations, the entire set of recipe parameters may be selected and determined through the execution of the RL algorithm. The ranges of the parameters are related to subsystem capability and capacity and are stored in the storage medium of the AI engine controller 202 of the AI machine 200.

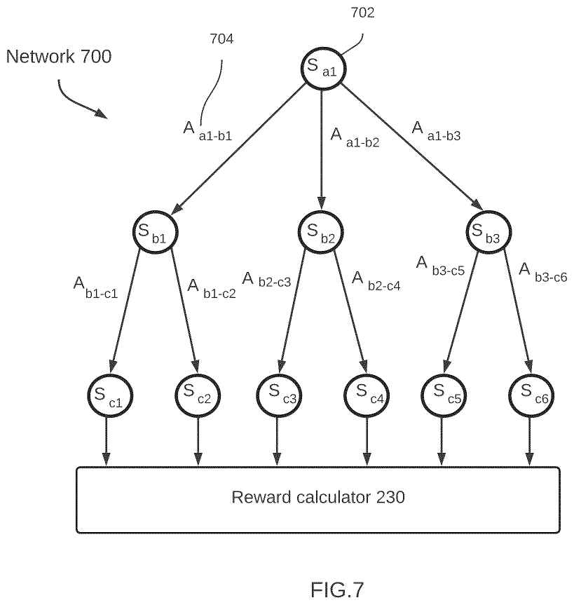

FIG. 7 schematically reveals a network 700 resulting from the RL process being rolled out through the MCTS algorithm. As shown in FIG. 7, nodes like node 702 are represented by circles. Each node is associated with a state, such as Sₐ₁. A parent node can lead to multiple child nodes upon the execution of actions such as 704. For example, the node with the state Sₐ₁ can transit into a node with the state S_{b1} resulting from the action A_{a1-b1}. The RL agent 224 manages the selection process through the policy neural network 226 and the MCTS program 228. For the ALE process, each action represents one ALE cycle with selected process recipe parameters although a half cycle could also be an option. The selection of an action continues until reaching a terminal state where criteria are met to calculate a reward by a reward calculator 230. For example, in the case of an ALE process, the reward may be calculated when a specific etching depth is reached.

A reward can be designed based on a cost function. A cost function for the ALE process is typically formulated as a square function pertaining to each output parameter of the structure post the ALE processing. The cost function can be defined as:

$$c = {\sum }_{i = I}^{N} {{w}_{i} ( {p}_{i} - {p}_{itarget} )}^{2} , \qquad [ 1 ]$$

where c is the cost, wᵢ is the weight, and pᵢ is a normalized output parameter like critical dimension at a selected vertical coordinate, p_{itarget} is the normalized target value of the output parameter, and N is serial number of the parameter. If multiple structures are evaluated, the cost function can be further expressed as:

$$C = {\sum }_{j = 1}^{M} {W}_{j} {c}_{j} , \qquad [ 2 ]$$

where C is the accumulated cost across multiple structures, Wⱼ is the weight, and cⱼ is the cost for one of the structures. The method can take several or many structures across a substrate like a 300 mm wafer. The method can further take different structures or different parts of the structure to quantify various loading effects. A reward can be designed as:

$$R = f ( c ) , \qquad [ 3 ]$$

Where R is the reward, and f is a function for determining the reward based on the cost c. In one implementation, the reward may be designed as multiple, or many discrete numbers based on the cost. For example, the range of the cost can be divided into 10 intervals. Each interval is represented by an integer.

Each time the RL process reaches the terminal node, the reward can be computed. Each state-action pair like (Sₐ₁, A_{a1-b1}), which is a part of state-action chain for the test case to receive the reward. A visit count for the pair will also be updated. After enough test cases are executed and an episode is completed, the average reward associated with each state-action pair can be calculated as the accumulated reward divided by the visit counts.

The value associated with a node can then be calculated by averaging the reward across all state-action pairs originating from the node. These data can be employed to train the policy neural network 226 to be more focused on generating actions with higher rewards.

In some implementations, the RL algorithm can be designed to be biased toward exploration rather than exploitation. For example, in a new episode for RL, the initial weights for the policy neural network can be assigned randomly. This can be a useful technique to prevent the RL process from being trapped in a local optimal point in the process recipe parameter space.

In other implementations, techniques like the e-greedy algorithm may be employed to expand the search tree. The algorithm allocates a part of the probability distribution to a completely random distribution and is well known in the art.

The ALE example provided is for illustration only. For a real RL process, the number of nodes could be substantial. The weights will be updated continuously to narrow down the selection of actions until the policy neural network 226 becomes deterministic. Subsequently, a process recipe can be generated for real-world applications.

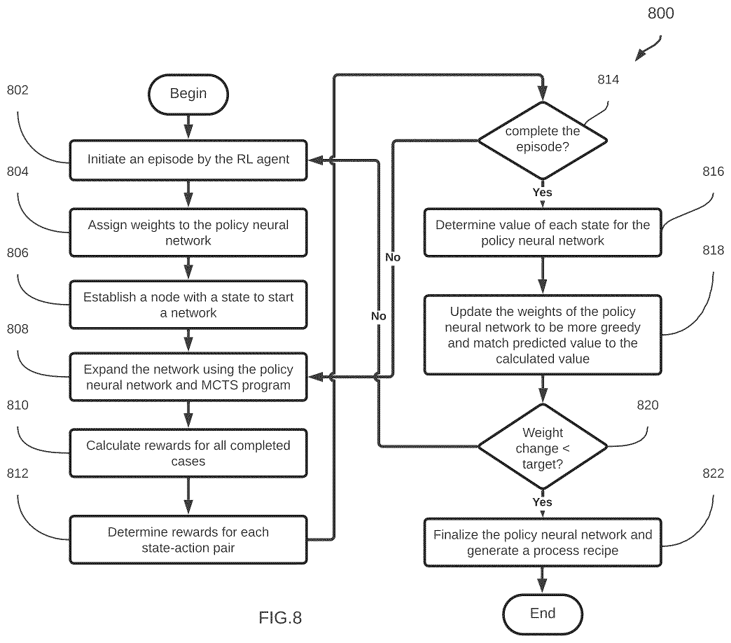

FIG. 8 showcases a flowchart for a process 800, which is a self-initiated process for autonomously generating a process recipe through an RL process. Process 800 starts with step 802, where the RL agent 224 initiates an episode for the RL process. An episode is represented by a network consisting of many nodes created by the MCTS program 228 enabled by the policy neural network 226. Each episode comprises many cases, wherein each case represents a completed simulation for a virtual process based on the system digital twin 204. For example, a case for an ALE process leads to a completed ALE process reaching the terminal state. The structures on the substrate have met a set of criteria, such as reaching the targeted etching depth. This typically includes a chain of actions and multiple or many intermediate states. A completed episode should deliver the rewards associated with state-action pairs and the value of the nodes.

In step 804, initial weights are assigned to the policy neural network 226. In one implementation, the weights are assigned randomly. In another implementation, the weights are based on a previous RL episode, enabling continuous improvement which makes the policy neural network 226 generate more optimal actions to increase reward.

In step 806, an initial node for a network is established. The initial node is associated with an initial state which describes an incoming substrate with a set of parameters as listed exemplarily in Table 2. At this point in time, the RL agent 224 applies the policy neural network 226 to generate probability distributions of selected recipe parameters. Based on the probability distribution, the MCTS program 228 is employed to generate an action with determined recipe parameters. A random number generator is typically applied based on the distribution to generate the action. Subsequently, the RL agent 224 applies the action by leveraging the system digital twin 204 to generate the next node with a new state. The process repeats until a case is completed.

In step 808, the network is expanded progressively using the policy neural network 226 and the MCTS program 228. Each state-action pair of the network is associated with a visit count. Some state-action pairs are involved in more than one case, which is accounted for by the visit count.

In step 810, rewards are calculated based on the reward calculator 230 for all completed cases. If the state-action pair is involved in a specific case, it will receive the reward accordingly in step 812. The reward accumulates as the visit count is increased. The average reward for a specific state-action pair is the accumulated rewards divided by the visit count of the state-action pair.

In step 814, the RL agent 224 judges if the episode is completed. A decision may be made by evaluating nodes in the network and completed cases against selected recipe parameters/discrete levels. If the result is negative, the RL agent 224 continues to expand the network. Otherwise, the RL agent 224 determines the value for each state in step 816. For each node associated with the state, the RL agent 224 has established relationships between state-action pairs and their associated rewards. The value of the node based on the current policy neural network can be computed as an average of the reward across all the state-action pairs originating from the node.

In step 818, the RL agent 224 updates the weights of the policy neural network 226 based on all available state-action pairs. At each node, the state is an input for the policy neural network 226, and a set of softmax/logistic function parameters are the outputs. The output also includes the predicted value. The updated weights should make the policy neural network more focused on generating actions with higher value and predicting the value more accurately. As the policy neural network 226 improves, it should become more deterministic in selecting an action from a group of available actions to generate the highest reward. This becomes a typical classification problem, hence a cost function for updating the policy neural network 226 should include a cross-entropy loss function and a squared error function for the value. The policy neural network 226 can be trained by leveraging rewards associated with all actions from the node. In one implementation, the earlier nodes may carry heavier weight during training to be consistent with a discount rule.

Different surface conditions and edge ring heights can be used as inputs to train the policy neural network 226. Hence the network can be used for an accurate prediction after being transmitted to the system controllers of the process systems for the real-world applications.

In step 820, the RL agent 224 evaluates if the weights have converged to give a deterministic policy neural network. If the result is negative, the RL agent 224 can initiate a new episode to repeat the process and generate more data through more exploration. In one implementation, an ¿-greedy algorithm may be employed to encourage exploration against exploitation. In another implementation, a new set of initial weights for the policy neural network 226 may be applied. In yet another implementation, the weights generated from the previous episode may be used together with the &-greedy algorithm.

If the evaluation in step 820 is positive, the policy neural network 226 is finalized in step 822. A process recipe can be generated accordingly. The finalized policy neural network 226 can be transmitted to the system controller 232 through the communication link 146. In a real processing event, when a state is known after calibration, the policy neural network can be employed to generate the actions in real-time. This can be considered an inference operation using the trained policy neural network 144.

The trained policy neural network 144 can be a result from more than one set of input and the output specifications. Since the training can be conducted in the background, a very large and deep neural network can be applied with a heavy data load. A generic ALE policy neural network for inputs with different types of stacks and critical dimensions and profile requirements is possible. There will be a broad spectrum of the implementation from a specialized policy neural network for a specific application to a more generic policy neural network for several or more applications. All such variations will fall within the inventive concept of the present invention.

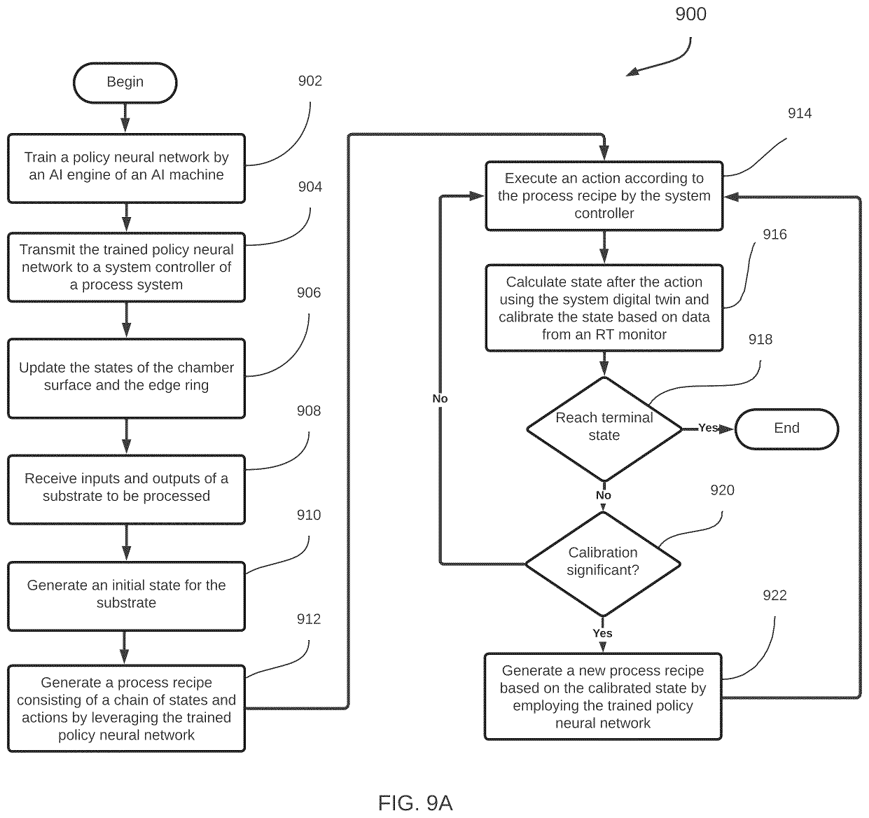

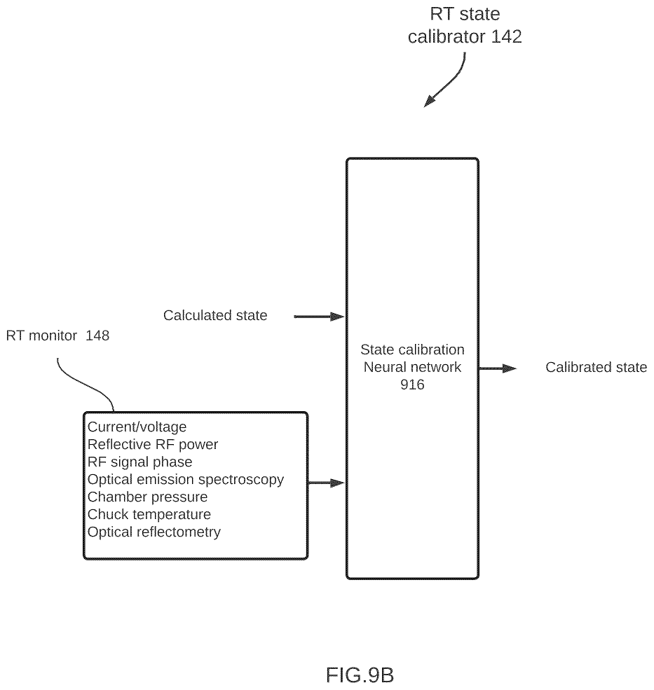

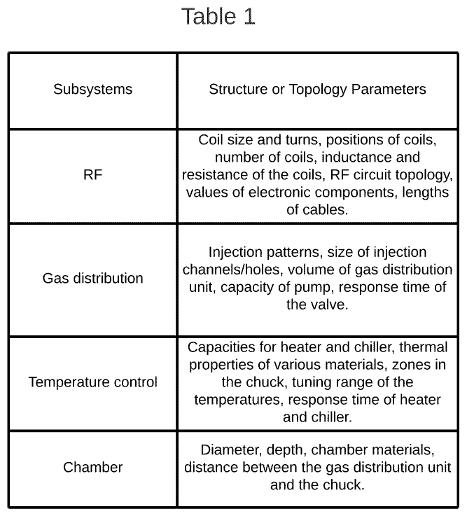

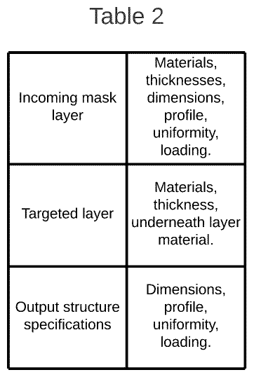

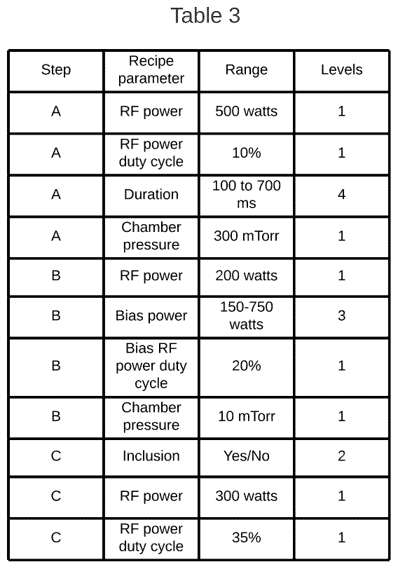

FIG. 9A illustrates a flowchart for real-time control of a process conducted in the process system 100. Process 900 starts with step 902 where the AI engine 140 receives inputs and output specifications for a substrate. In step 904, a policy neural network is trained by the AI engine 140 of the AI machine 200. The trained policy neural network 144 is then transmitted from the AI machine 200 to the system controller 132 through the communication link 146. The trained policy neural network 144 can be transmitted to multiple system controllers of a fleet of process systems. Upon receiving the trained policy neural network 144, the system controller 132 is ready to generate a process recipe for a substrate to be processed in the plasma process chamber 104. In some instances, the trained neural network 144 may have been stored in a storage medium of the system controller 132 and will be retrieved for generating the process recipe. In step 906, states of the chamber interior surface and the edge ring are updated using their digital twins, respectively. Herein, the ages of the surfaces and the edge ring being exposed to the plasma are the inputs of the digital twins along with other parameters including parameters related to the cleaning procedures during the PM.

In step 908, the system controller 132 receives inputs and output specifications of the substrate to be processed. An initial state of the substrate is generated in step 910, which utilizes a set of parameters to describe the structures of the incoming substrate. In step 912, a process recipe is generated by the system controller 132 by employing the trained policy neural network 144. The process recipe consists of a chain of actions in the form of state-action pairs. In step 914, the system controller 132 executes an action according to the process recipe. For example, the action may be a cycle including the surface modification and the sputtering steps of an ALE process. In step 916, the state is calculated as a result of the action by the system controller.

The calculated state is subsequently calibrated using a state calibration neural network 916. The neural network 916 is a trained neural network. The training can be conducted based on both simulated and measured data. For example, an intermediate state can be calculated and compared with a measurement to train the neural network 916. Taking an ALE process as an example, a profile during the etching process can be predicted using the system digital twin 140. Subsequently, a transmission electron microscopy (TEM) technique is applied to a substrate pulled out from the plasma process chamber at the step to obtain a real-world profile of the structure. The difference between the real-world data and the simulated data serves as a set of training data for the neural network 916. In some other implementations, optical reflectometry techniques may be utilized to generate the real-world data.

As shown in FIG. 9B, the state calibration neural network 916 takes the calculated state as one of the inputs. It takes outputs of the RT monitor 148 as another input. The calibrated state is the output of the neural network 916. The RT monitor 148 includes various sensors as listed exemplarily in FIG. 9B. These include, but are not limited to, an IV probe for measuring RF current/voltage, an RF power sensor for measuring reflective RF power, phase sensors for measuring RF current or voltage phases, optical emission spectroscopy sensors for measuring neutral compositions inside the chamber, a manometer for chamber pressure, temperature sensors for measuring chuck temperature, and a sensor for an optical reflectometry technique for measuring the progression of the structures of the substrate. In step 918, the system controller 132 evaluates if the terminal state has been reached based on the calibrated state. The terminal state represents the end point of the process. If the terminal state is reached, process 900 is completed. Otherwise, the system controller 132 evaluates in step 920 if the calibration of the state is significant enough to trigger step 922 to generate a new process recipe based on the calibrated state by employing the trained policy neural network 144. A squared error function can be constructed to measure a difference between the calculated and the calibrated state. The error function includes a selected set of parameters describing the state. If the normalized error is above a predefined target, the process recipe will be regenerated for the remaining process step.

In one implementation, the actions for the remaining process are generated at once. In another implementation, the action for the next step only is generated. The state will be calibrated, and the action will be generated step by step. At step 920, if the calibration is insignificant, steps 914 and 918 will be repeated until reaching the terminal state.

1. A control module for a semiconductor process system, comprising:
a plurality of subsystem controllers for controlling operations of a plurality of subsystems;
an AI engine for autonomously generating a process recipe through training of a policy neural network by applying an RL algorithm; and
a system controller for autonomously adjusting the process recipe during the processing of a substrate, wherein adjusting is carried out by utilizing the trained policy neural network and data provided by an RT monitor.

2. The control module of claim 1, wherein the AI engine is a part of an AI machine in the cloud and the AI machine is coupled to the system controller through a communication link.

3. The control module of claim 1, wherein the AI engine further comprises an AI engine controller, which leverages an RL engine to generate the process recipe based on a system digital twin.

4. The control module of claim 3, wherein the system digital twin further includes an RF digital twin, a gas digital twin, a temperature digital twin, a chamber plasma digital twin, a chamber surface aging digital twin, an edge ring digital twin, and a process digital twin.

5. The control module of claim 3, wherein the RL engine further includes an RL agent, an MCTS program, and a reward calculator.

6. The control module of claim 1, wherein the policy neural network includes an input layer, multiple hidden layers, and an output layer, wherein the output layer comprises multiple parts, each part providing outputs that describe probability distributions of selected process recipe parameters using softmax and/or logistic functions across various discretized levels.

7. The control module of claim 1, wherein the RT monitor further includes a plurality of sensors for measuring parameters of an RF subsystem, a gas subsystem, and a temperature subsystem.

8. The control module of claim 1, wherein the RT monitor further includes a sensor for optical emission spectroscopy for monitoring a plasma inside a plasma process chamber.

9. The control module of claim 1, wherein the RT monitor further includes a sensor for optical reflectometry to determine structure parameters of an etching process.

10. The control module of claim 1, wherein the system controller adjusts the process recipe based on a comparison between the calculated state and the calibrated state, wherein the state represents the structures of the substrate being processed.

11. The control module of claim 1, wherein the control module is a part of etching or deposition process systems.

12. An AI machine, comprising:
a plurality of hardware and software modules optimized for AI applications; and
an AI engine built upon the hardware and software modules, wherein the AI engine autonomously trains a policy neural network through an RL process, and wherein the trained policy neural network is transmitted to a system controller of a process system for generating and adjusting a process recipe in real-time based on data provided by an RT monitor.

13. The AI machine of claim 12, wherein the AI machine is connected to a plurality of process systems through a plurality of communication links, wherein the trained policy neural network is deployed for the plurality of process systems.

14. The AI machine of claim 12, wherein the system controller receives the trained policy neural network and generates a process recipe in real-time based on inputs and output specifications of a substrate to be processed, wherein the system controller further leverages outputs from a chamber surface aging digital twin and an edge ring digital twin.

15. The AI machine of claim 12, wherein the AI engine further comprises an AI engine controller, which leverages an RL engine to generate the process recipe based on a system digital twin.

16. The AI machine of claim 15, wherein the RL engine further includes an RL agent, an MCTS program, and a reward calculator.

17. A method for real-time control of a semiconductor process system, comprising:
a) training a policy neural network by an AI engine of an AI machine through a reinforcement learning (RL) process;
b) transmitting the trained policy neural network to a system controller of the process system through a communication link;
c) updating chamber surface aging and edge ring digital twins, wherein the digital twins provide additional inputs to the trained policy neural network;
d) receiving inputs and output specifications of a substrate to be processed by the process system;
e) generating an initial state of the substrate based on the inputs;
f) generating a process recipe consisting of a chain of actions by leveraging the trained policy neural network;
g) executing an action by the system controller according to the process recipe;
h) calculating the post-action state of the substrate by the system controller according to a system digital twin;
i) calibrating the calculated state based on data provided by an RT monitor;
j) regenerating the process recipe for the remaining process steps by the trained policy neural network if a difference between the calculated and the calibrated state is above a predefined target; and
k) repeating steps g) to j) until a terminal state is reached.

18. The method of claim 17, wherein the method further comprises providing data by the RT monitor using a plurality of sensors, which measure parameters of an RF subsystem, a gas subsystem, and a temperature subsystem.

19. The method of claim 17, wherein the method further comprises providing data by the RT monitor using a sensor for optical emission spectroscopy and/or a sensor for optical reflectometry.

20. The method of claim 17, wherein the digital twins for the chamber surface aging and the edge ring take into account the duration that chamber interior surfaces are exposed to the plasma, as well as the cleaning procedures of a preventive maintenance procedure.
